(19) United States
(12) Patent Application Publication
(10) Pub. No.: US 2026/0353805 A1
(43) Pub. Date: Nov. 5, 2026

(54) DISPLAY SUBSTRATE, DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Bo ZHANG, Beijing (CN); Yang ZENG, Beijing (CN); Yi QU, Beijing (CN); Aoyuan FENG, Beijing (CN); Bin LI, Beijing (CN)

(21) Appl. No.: 19/488,735

(22) PCT Filed: May 14, 2024
(86) PCT No.: PCT/CN2024/093037

§ 371 Date: Nov. 28, 2025

(30) Foreign Application Priority Data
Jun. 1, 2023 (CN) 202310644939.0

(51) Int. Cl. H10D 86/40; H10D 86/60

(52) U.S. Cl. CPC H10D 86/443; H10D 86/60

(57) ABSTRACT

The embodiments of the present disclosure provides a display substrate, a display panel and a display apparatus. The display substrate includes a base substrate, the base substrate including a display area and a peripheral area located on a side of the display area, and the peripheral area includes a first bonding area and a wiring area surrounding the first bonding area; the display substrate includes, in the wiring area, a plurality of data connection lines; a first shielding pattern electrically connected to a first voltage connection line; and a plurality of multiplexing signal lines, where each multiplexing signal line includes a first connection line, a second connection line, and a third connection line connecting the first connection line with the second connection line, and the first connection lines of the plurality of multiplexing signal lines are all located on a same side of the first bonding area in a second direction; the plurality of data connection lines, the first shielding pattern, and the second connection lines are sequentially stacked in a direction away from the base substrate; and an orthographic projection of each second connection line on the base substrate overlaps with an orthographic projection of a corresponding data connection line on the base substrate to form an overlapping part, and the overlapping part is located in an orthographic projection of the first shielding pattern on the base substrate.

### TECHNICAL FIELD

The present disclosure relates to the field of display technology, in particular to a display substrate, a display panel and a display apparatus.

### BACKGROUND

A display substrate includes a base substrate, and a plurality of data lines and a plurality of gate lines which are arranged on the base substrate, where a plurality of pixel units are defined by the data lines and the gate lines. In general, when a gate driving signal is supplied to a gate line, data voltages are supplied to the pixel units in the same row, and then the pixel units display light of various brightness according to magnitudes of the data voltages. The display substrate may further include a plurality of multiplexing signal lines connected to the data lines, configured to input a data signal of each frame of a display image to the corresponding signal lines, and to correspondingly input trigger signals to the pixel units of different colors in a time-division manner for each frame of the display image.

### SUMMARY

Embodiments of the present disclosure provide a display substrate, a display panel and a display apparatus.

In a first aspect, an embodiment of the present disclosure provides a display substrate, including a base substrate, where the base substrate includes a display area and a peripheral area located on a side of the display area, and the peripheral area includes a first bonding area and a wiring area surrounding the first bonding area;
in the wiring area, the display substrate includes:
a plurality of data connection lines extending along a first direction;
a first shielding pattern electrically connected to a first voltage connection line; and
a plurality of multiplexing signal lines, wherein each multiplexing signal line includes a first connection line, a second connection line, and a third connection line connecting the first connection line with the second connection line, and the first connection lines of the plurality of multiplexing signal lines are all located on the same side of the first bonding area in a second direction, and wherein
the plurality of data connection lines, the first shielding pattern, and the second connection lines are sequentially stacked in a direction away from the base substrate; and
an orthographic projection of each second connection line on the base substrate overlaps with an orthographic projection of a corresponding data connection line on the base substrate to form an overlapping part, and the overlapping part is located in an orthographic projection of the first shielding pattern on the base substrate.

In some implementations, in the first bonding area, the display substrate includes a plurality of first bonding terminals configured to be connected to a driving chip; and
one end of each data connection line is connected to a corresponding first bonding terminal, and the other end of the data connection line extends to the display area and is connected to a data line in the display area.

In some implementations, the peripheral area further includes a second bonding area located on a side of the first bonding area away from the display area, and in the second bonding area, the display substrate includes a plurality of second bonding terminals configured to be connected to a flexible printed circuit board;
each multiplexing signal line further includes: a fourth connection line, one end of the fourth connection line is connected to the second connection line, and the other end of the fourth connection line extends to the display area; and
the first connection lines are connected to corresponding second bonding terminals.

In some implementations, the plurality of data connection lines include a plurality of first data connection lines and a plurality of second data connection lines, and orthographic projections of the plurality of first data connection lines on the base substrate and orthographic projections of the plurality of second data connection lines on the base substrate are respectively located on two opposite sides of an orthographic projection of the fourth connection line on the base substrate in the second direction; and
the orthographic projection of the first shielding pattern on the base substrate overlaps with the orthographic projections of the plurality of first data connection lines on the base substrate.

In some implementations, in the wiring area, the display substrate further includes: a second shielding pattern electrically connected to the first voltage connection line; and
an orthographic projection of the second shielding pattern on the base substrate overlaps with the orthographic projections of the plurality of second data connection lines on the base substrate.

In some implementations, the first voltage connection line includes: a first portion connection line, a second portion connection line, and a first voltage connection pattern located between the first portion connection line and the second portion connection line;
wherein the first portion connection line and the second portion connection line are connected to corresponding second bonding terminals, and the first voltage connection pattern is connected to a conductive pattern located in the display area; and
the first shielding pattern and the second shielding pattern are connected to the first voltage connection pattern.

In some implementations, the wiring area includes a first wire passing area and a second wire passing area, and the first wire passing area, the first bonding area and the second wire passing area are arranged in the second direction;
the first portion connection line passing through the first wire passing area and is connected to a corresponding second bonding terminal, and the second portion connection line passes through the second wire passing area and is connected to a corresponding second bonding terminal; and
the first voltage connection pattern is located on a side of the first bonding area close to the display area.

In some implementations, the first shielding pattern, the second shielding pattern and the first voltage connection line are disposed in the same layer.

In some implementations, in the wiring area, the display substrate further includes: a second voltage connection line in the same layer as the first voltage connection line, and one end of the second voltage connection line is connected to a corresponding second bonding terminal;
the second voltage connection line includes a third portion connection line and a fourth portion connection line, and wherein
the third portion connection line passes through the first wire passing area and is connected to a corresponding second bonding terminal, and the third portion connection line is located on a side of a first portion away from the first bonding area; and
the fourth portion connection line passes through the second wire passing area and is connected to a corresponding second bonding terminal, and the fourth portion connection line is located on a side of the second portion connection line away from the first bonding area.

In some implementations, an orthographic projection of the second portion connection line on the base substrate and an orthographic projection of the fourth portion connection line on the base substrate both overlap with an orthographic projection of the third connection line on the base substrate.

In some implementations, in the first bonding area, the display substrate includes a plurality of first bonding terminals configured to be connected to a driving chip;
the peripheral area further includes a second bonding area located on a side of the first bonding area away from the display area, and in the second bonding area, the display substrate includes a plurality of second bonding terminals configured to be connected to a flexible printed circuit board; and
in the wiring area, the display substrate further includes a plurality of terminal connection lines configured to be connected to the plurality of first bonding terminals and the plurality of second bonding terminals.

In some implementations, in the peripheral area, the display substrate includes: a first conductive layer, a first insulating layer and a second conductive layer located on a side of the base substrate and sequentially arranged in the direction away from the base substrate; and
some of the plurality of data connection lines are located in the first conductive layer, and others are located in the second conductive layer.

In some implementations, the third connection lines are located in the first conductive layer and/or the second conductive layer.

In some implementations, the fourth connection line is located in the first conductive layer and/or the second conductive layer.

In some implementations, in the peripheral area, the display substrate further includes: a third conductive layer;
the third conductive layer is located on a side of the second conductive layer away from the base substrate, and the display substrate further includes an interlayer dielectric layer arranged between the second conductive layer and the third conductive layer; and
the first connection lines are located in the third conductive layer.

In some implementations, the third connection line includes a first portion located in the first conductive layer and a second portion located in the second conductive layer; and
the first connection line is connected to the second portion through at least one first via hole penetrating through the interlayer dielectric layer, and the first connection line is connected to the first portion through at least one second via hole penetrating through the interlayer dielectric layer and the insulating layer.

In some implementations, in the peripheral area, the display substrate further includes: a fourth conductive layer;
the fourth conductive layer is located on a side of the third conductive layer away from the base substrate, the display substrate further includes a passivation layer and a planarization layer arranged between the third conductive layer and the fourth conductive layer, and the planarization layer is located on a side of the passivation layer away from the third conductive layer; and
the second connection line is located in the fourth conductive layer.

In some implementations, the third connection line includes a first portion located in the first conductive layer and a second portion located in the second conductive layer,
the third conductive layer further includes an adapter pattern;
the first portion is connected to the adapter pattern through at least one third via hole penetrating through the interlayer dielectric layer and the insulating layer, and the second portion is connected to the adapter pattern through at least one fourth via hole penetrating through the interlayer dielectric layer; and
the adapter pattern is connected to the second connection line through at least one fifth via hole penetrating through the passivation layer and the planarization layer.

In a second aspect, an embodiment of the present disclosure provides a display panel including the display substrate provided in the first aspect.

In a third aspect, an embodiment of the present disclosure provide a display apparatus, including the display panel provided in the second aspect.

In the display substrate provided by the embodiment of the present disclosure, the display substrate includes, in the peripheral area, the plurality of multiplexing signal lines and a plurality of data connection lines, the second connection line of the multiplexing signal line overlaps with the corresponding data connection line in a thickness direction of the display substrate to form an overlapping part, and the first shielding pattern is additionally provided in the overlapping part. The first shielding pattern is located between the data connection line and the second connection line, and the first shielding pattern is connected to the first voltage connection line capable of supplying a stable voltage signal, so that the first shielding pattern can avoid the fluctuation in signal in the second connection line due to the jump in the voltage in the data connection line, and shield the interference of the data connection line on the second connection lines, that is, the multiplexing signal lines, thereby improving the stability of the signals provided through the multiplexing signal lines, and eliminating the mura defect of the display picture.

### BRIEF DESCRIPTION OF DRAWINGS

The accompanying drawings, which are provided for further understanding of the present disclosure and constitute a part of this specification, are for explaining the present disclosure together with the embodiments of the present disclosure, but are not intended to limit the present disclosure. In the drawings:

FIG. 1 is a schematic plan view illustrating a structure of a display substrate according to an embodiment of the present disclosure.

FIG. 2 is a schematic plan view illustrating a structure of a peripheral area of a display substrate according to an embodiment of the present disclosure.

FIG. 3 is a cross-sectional view of the structure in FIG. 2 taken along a line AA′.

FIG. 4 is a schematic structural diagram of a first conductive layer in the peripheral area according to an embodiment of the present disclosure.

FIG. 5 is a schematic structural diagram of a second conductive layer in the peripheral area according to an embodiment of the present disclosure.

FIG. 6 is a schematic structural diagram of a third conductive layer in the peripheral area according to an embodiment of the present disclosure.

FIG. 7 is a schematic structural diagram of a fourth conductive layer in the peripheral area according to an embodiment of the present disclosure.

FIG. 8 is an enlarged schematic diagram of an area Q1 in FIG. 2.

FIG. 9 is a cross-sectional view of the structure in FIG. 8 taken along a line BB′.

FIG. 10 is an enlarged schematic diagram of an area Q2 in FIG. 2.

FIG. 11 is a cross-sectional view of the structure in FIG. 10 taken along a line CC′.

FIG. 12 is a schematic structural diagram of an active semiconductor layer in a peripheral area according to an embodiment of the present disclosure.

FIG. 13 is a schematic diagram of an etch bending B mask according to an embodiment of the present disclosure.

FIG. 14 is a schematic structural diagram of a display area according to an embodiment of the present disclosure.

### DESCRIPTION OF THE REFERENCE NUMERALS

a display area AA, a peripheral area NA, a wiring area PA, a first bonding area BA1, a second bonding area BA2, a first wire passing area QA1 and a second wire passing area QA2;
a first direction Y and a second direction X;
a base substrate 10, a buffer layer BUF, an active semiconductor layer Poly, a second insulating layer GI2, a first conductive layer M1, a first insulating layer GI1, a second conductive layer M2, an interlayer dielectric layer ILD, a third conductive layer M3, a passivation layer PVX, a planarization layer PLN and a fourth conductive layer M4;
a data connection line DL: a first data connection line DL1 and a second data connection line DL2;
a multiplexing signal line MUX: a first connection line L1, a second connection line L2, a third connection line L3, a fourth connection line L4, a first portion L31, and a second portion L32;
a first shielding pattern S1 and a second shielding pattern S2;
a first voltage connection line VDD: a first portion connection line VDD1, a second portion connection line VDD2 and a first voltage connection pattern VDD3;
a second voltage connection line VSS: a third portion connection line VSS1, and a fourth portion connection line VSS2;
a first bonding terminal BA10, a second bonding terminal BA20 and a terminal connection line 120;
a first via K1, a second via K2, a third via K3, a fourth via K4 and a fifth via K5;
an adapter pattern Z0, and an adapter electrode Z; and
a thin film transistor TFT: a source electrode T1, a drain electrode T2, a gate electrode Gate, and an active pattern Act.

### DETAIL DESCRIPTION OF EMBODIMENTS

The embodiments of the present disclosure will be described in detail below with reference to the accompanying drawings. It should be understood that the embodiments described here are merely used to illustrate and explain the present disclosure, not to limit the present disclosure.

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few embodiments of the present disclosure, and not all embodiments. All other embodiments, which can be derived by a person skilled in the art from the described embodiments of the present disclosure without any creative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term of “comprising”, “including”, or the like, means that the element or item preceding the term contains the element or item listed after the term and its equivalent, but does not exclude other elements or items. The term “connected/connecting”, “coupled/coupling”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

A display substrate includes a base substrate, and a plurality of data lines and a plurality of gate lines which are arranged on the base substrate, where a plurality of pixel units are defined by the data lines and the gate lines. In general, when a gate driving signal is supplied to a gate line, data voltages are supplied to pixel units in the same row, and then the pixel units display light of corresponding brightness according to magnitudes of the data voltages. The display substrate may further include a plurality of multiplexing signal lines connected to the data lines, configured to input data signals of each frame of display image to corresponding signal lines, and to correspondingly input trigger signals to the pixel units of different colors in a time-division manner for each frame of display image.

In the related art, the multiplexing signal lines overlap with data connection lines in a thickness direction of the display substrate, a parasitic capacitance is occurred at the overlapping position, so that a jump of a data voltage supplied through the data connection lines portions causes fluctuation of the signals in the multiplexing signal lines, thereby causing the mura defect of a picture displayed by the display substrate.

In order to solve at least one of the above technical problems, an embodiment of the present disclosure provides a display substrate, where a shielding electrode is additionally disposed between the multiplexing signal lines and the data connection lines in a area where the multiplexing signal lines overlap with the data connection lines, and is configured to shield the interference on the signals in the multiplexing signal lines, thereby avoiding the mura defect of the displayed picture.

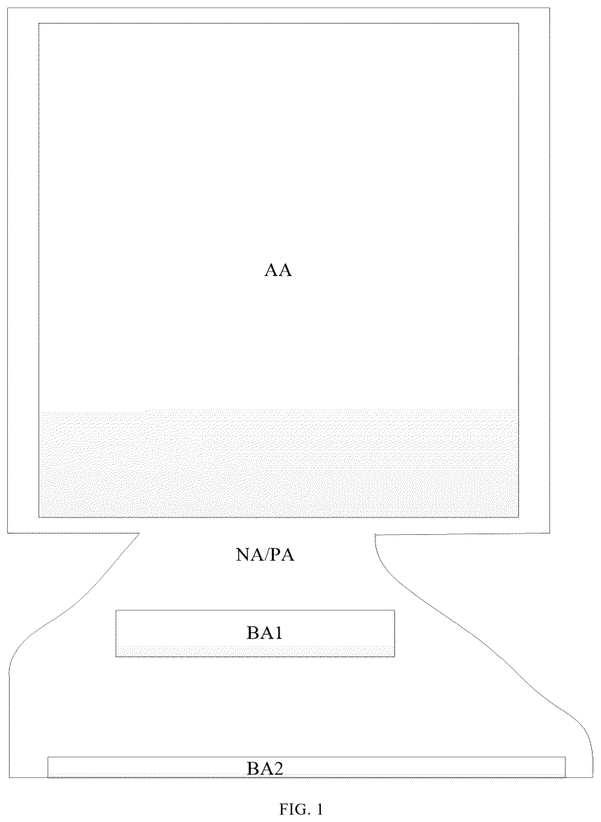

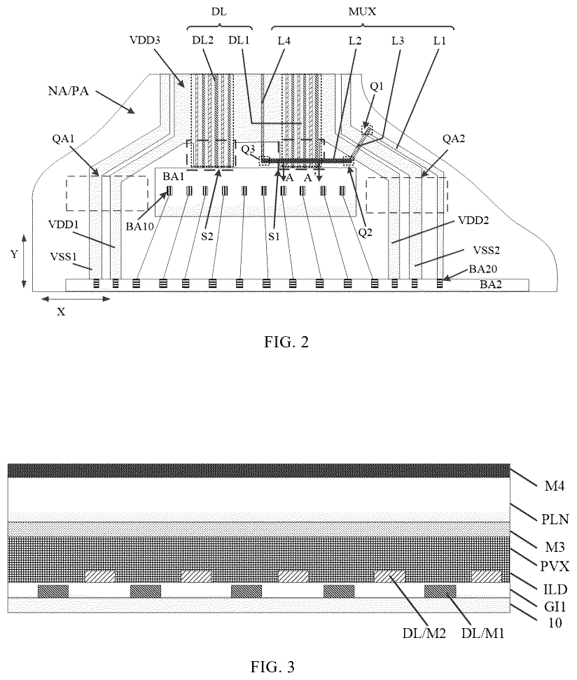

FIG. 1 is a schematic plan view illustrating a structure of a display substrate according to an embodiment of the present disclosure. FIG. 2 is a schematic plan view illustrating a structure of a peripheral area of a display substrate according to an embodiment of the present disclosure. As shown in FIG. 1 and FIG. 2, the display substrate includes a base substrate 10, the base substrate 10 includes a display area AA and a peripheral area NA located on a side of the display area AA, and the peripheral area NA includes a first bonding area BA1 and a wiring area PA surrounding the first bonding area BA1.

The display substrate includes, in the wiring area PA, a plurality of data connection lines DL, a first shielding pattern S1, and a plurality of multiplexing signal lines MUX. The signal lines extend along a first direction Y; the first shielding pattern S1 is electrically connected to a first voltage connection line VDD; the multiplexing signal lines MUX each include a first connection line L1, a second connection line L2, and a third connection line L3 connecting the first connection line L1 with the second connection line L2, and the first connection lines L1 of the plurality of multiplexing signal lines MUX are all located on a same side of the first bonding area BA1 in a second direction X.

The data connection lines DL, the first shielding pattern S1, and the second connection lines L2 are sequentially stacked in a direction away from the base substrate 10; an orthographic projection of each second connection line L2 on the base substrate 10 overlaps with an orthographic projection of a corresponding signal line on the base substrate 10 to form an overlapping part, and the overlapping part is located in an orthographic projection of the first shielding pattern S1 on the base substrate 10.

It should be understood that the above signal lines may be signal lines electrically connected to the data lines in the display area AA; and the first voltage connection line VDD is configured to provide a stable voltage signal and may be a VDD power line configured to provide a low level signal. In another embodiment, the first voltage connection line VDD may alternatively be a VSS power line configured to provide a high level signal, which is not limited in the embodiments of the present disclosure.

In the display substrate provided by the embodiment of the present disclosure, the display substrate includes, in the peripheral area NA, the plurality of multiplexing signal lines MUX and a plurality of signal lines, the second connection line L2 of each multiplexing signal line MUX overlaps with the corresponding signal line in a thickness direction of the display substrate, and the first shielding pattern S1 is additionally provided in the overlapping area. The first shielding pattern S1 is located between the signal line and the second connection line L2, and the first shielding pattern S1 is connected to the first voltage connection line VDD capable of supplying a stable voltage signal, so that the first shielding pattern S1 can avoid the fluctuation in the signal in the second connection line L2 due to the jump in the voltage in the signal line, and shield the interference of the signal line on the second connection line L2, that is, the multiplexing signal line MUX, thereby improving the stability of the signals provided through the multiplexing signal line MUX, and eliminating the mura defect of the display picture.

In some implementations, the display substrate includes, in the first bonding area BA1, a plurality of first bonding terminals BA10 configured to be connected to a driving chip. The display substrate further includes, in the peripheral area NA, a second bonding area BA2, the second bonding area BA2 is located on a side of the first bonding area BA1 away from the display area AA, the display substrate includes, in the second bonding area BA2, a plurality of second bonding terminals BA20, and the second bonding terminals BA20 are configured to be connected to a flexible printed circuit board. The display substrate further includes, in the wiring area PA, a plurality of terminal connection lines 120 configured to be connected to the first bonding terminals BA10 and the second bonding terminals BA20.

Specifically, the display substrate may be bonded to the flexible printed circuit board through the second bonding terminals BA20, so as to write an external signal into the driving chip through the flexible printed circuit board, so that the driving chip controls the display substrate to display pictures.

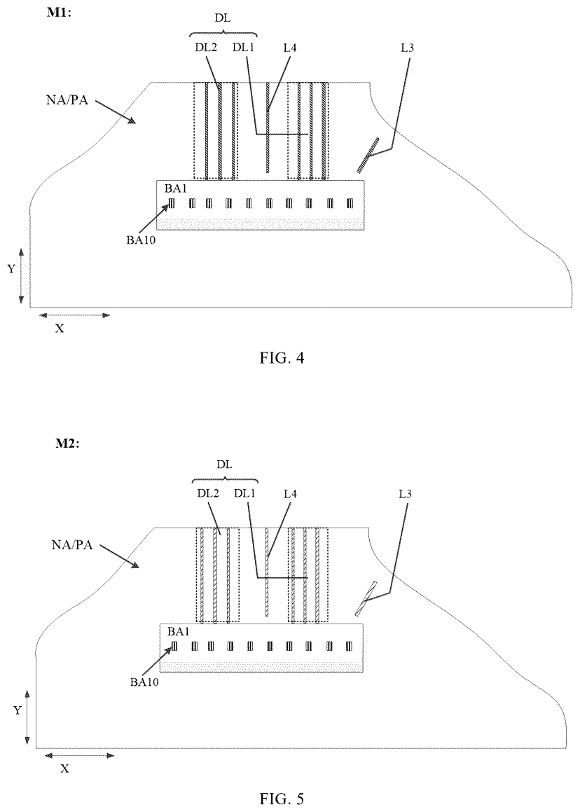

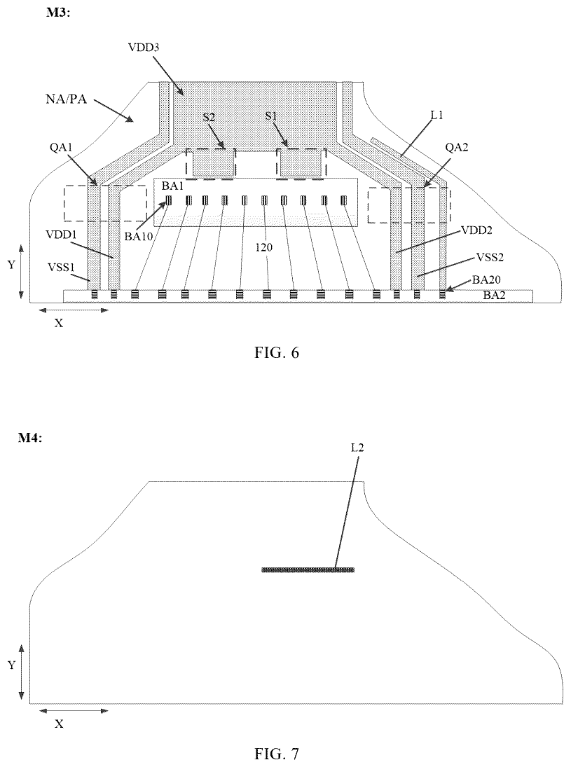

FIG. 3 is a cross-sectional view of the structure in FIG. 2 taken along a line AA′. FIG. 4 is a schematic structural diagram of a first conductive layer in the peripheral area according to an embodiment of the present disclosure. FIG. 5 is a schematic structural diagram of a second conductive layer in the peripheral area according to an embodiment of the present disclosure. FIG. 6 is a schematic structural diagram of a third conductive layer in the peripheral area according to an embodiment of the present disclosure. FIG. 7 is a schematic structural diagram of a fourth conductive layer in the peripheral area according to an embodiment of the present disclosure.

As shown in FIG. 3, the display substrate includes, in the peripheral area NA, a base substrate 10, and a first conductive layer M1, a first insulating layer GI1, a second conductive layer M2, an interlayer dielectric layer ILD, a third conductive layer M3, a passivation layer PVX, a planarization layer PLN, and a fourth conductive layer M4, which are located on a side of the base substrate 10 and sequentially arranged in a direction away from the base substrate 10.

In some implementations, the data connection lines DL, the first shielding pattern S1, and the second connection lines L2 are sequentially stacked in the direction away from the base substrate 10; the data connection lines DL are located in the first conductive layer M1 or the second conductive layer M2, the first shielding pattern S1 is located in the third conductive layer M3, and the second connection lines L2 are located in the fourth conductive layer M4. Compared with the case in the related art that the second connection lines L2 and the data connection lines DL are separated from each other by only the first insulating layer GI1, or the first insulating layer GI1 and the interlayer dielectric layer ILD, in the embodiment of the present disclosure, the second connection lines L2 are arranged in the fourth conductive layer M4, and the shielding pattern is additionally arranged in the third conductive layer M3. By increasing a distance between the second connection lines L2 and the data connection lines DL and by providing the shielding pattern between the second connection lines L2 and the data connection lines DL, the influence between the multiplexing signal lines MUX and the data connection lines DL due to the parasitic capacitance is shielded, and the fluctuation in the signals in the multiplexing signal lines MUX due to the jump in voltage in the data voltages provided through the data connection lines DL is avoided, thereby eliminating the mura defect of the display picture.

In some implementations, one end of each data connection line DL is connected to the corresponding first bonding terminal BA10, and the other end of each data connection line DL extends to the display area AA and is connected to the corresponding data line in the display area AA. That is, the data connection lines DL are configured to provide data voltages to the display area AA through the driving chip, and the data voltages are output to the corresponding pixel units through the data lines in the display area AA.

As shown in FIGS. 3 to 5, some of the plurality of data connection lines DL are disposed in the first conductive layer M1, and others are disposed in the second conductive layer M2. In an example, two adjacent signal lines in the second direction X are located in different conductive layers. It should be understood that the data connection lines DL are connected to the data lines in the display area AA, the data connection lines DL connected to the data lines corresponding to odd-numbered columns of pixel units may be located in one of the first conductive layer M1 and the second conductive layer M2, and the data connection lines DL connected to the data lines corresponding to even-numbered columns of pixel units may be located in the other of the first conductive layer M1 and the second conductive layer M2.

In some implementations, as shown in FIG. 2, the plurality of data connection lines DL include a plurality of first data connection lines DL1 and a plurality of second data connection lines DL2, and the plurality of first data connection lines DL1 and the plurality of second data connection lines DL2 are respectively located on two opposite sides of the fourth connection line L4 in the second direction X; and the orthographic projection of the first shielding pattern S1 on the base substrate 10 overlaps with orthographic projections of the plurality of first data connection lines DL1 on the base substrate 10.

It should be noted that in the foregoing embodiment, some of the plurality of data connection lines DL are disposed in the first conductive layer, and others are disposed in the second conductive layer M2. In addition, the first data connection lines DL1 and the second data connection lines DL2 are only located in different areas, and are respectively disposed on two opposite sides of the fourth connection lines L4 in the second direction X. However, in terms of the layers where the first data connection lines DL1 and the second data connection lines DL2 are located, some of the first data connection lines DL1/the second data connection lines DL2 are disposed in the first conductive layer, and others are disposed in the second conductive layer M2.

The first shielding pattern S1 can avoid the fluctuation in the signals in the second connection lines L2 due to the jump in the voltage in the first data connection lines DL1, and shield the interference of the first data connection lines DL1 on the second connection lines L2, that is, the multiplexing signal lines MUX, thereby improving the stability of the signals provided through the multiplexing signal lines MUX, and eliminating the mura defect of the display picture.

In some implementations, as shown in FIG. 3, the display substrate further includes, in the wiring area PA, a second shielding pattern S2 electrically connected to the first voltage connection line VDD; and an orthographic projection of the second shielding pattern S2 on the base substrate 10 overlaps with orthographic projections of the plurality of second data connection lines DL2 on the base substrate 10.

It should be understood that in order to ensure the consistency of the resistances and capacitances of the plurality of first data connection lines DL1 and the plurality of second data connection lines DL2, the second shielding pattern S2 is additionally provided. The second shielding pattern S2 is connected to a first portion connection line VDD1, that is, the second shielding pattern S2 is connected to the first voltage connection line VDD, so that the first voltage connection line VDD can provide a stable voltage signal, and therefore, crosstalk of other signals can be shielded to ensure the stability of the data signals provided through the signal lines.

In some implementations, as shown in FIG. 2, the first voltage connection line VDD includes: the first portion connection line VDD1 and a second portion connection line VDD2 connected to each other, and a first voltage connection pattern VDD3 located between the first portion connection line VDD1 and the second portion connection line VDD2. The first portion connection line VDD1 and the second portion connection line VDD2 are both connected to the second bonding terminals BA20, and the first voltage connection pattern VDD3 is connected to a conductive pattern located in the display area AA. As shown in FIGS. 3 and 6, the first voltage connection line VDD is located in the third conductive layer M3.

As shown in FIG. 3, the first shielding pattern S1 and the second shielding pattern S2 are connected to the first voltage connection pattern VDD3. In the embodiment of the present disclosure, the first voltage connection line VDD is configured to transmit a first operating voltage signal, for example, a low level voltage signal.

Further, in some implementations, as shown in FIG. 2, the wiring area PA includes a first wire passing area QA1 and a second wire passing area QA2, and the first wire passing area QA1, the first bonding area BA1 and the second wire passing area QA2 are arranged in the second direction X, and the first connection lines L1 of the multiplexing signal lines MUX are connected to the second bonding terminals BA20 by passing through the second wire passing area QA2.

As shown in FIG. 2, the first portion connection line VDD1 passes through the first wire passing area QA1 and is connected to the second bonding terminal BA20, and the second portion connection line VDD2 passes through the second wire passing area QA2 and is connected to the second bonding terminal BA20; the first voltage connection pattern VDD3 is connected to the first portion connection line VDD1 and the second portion connection line VDD2, and is located on a side of the first bonding area BA1 close to the display area AA, as shown in FIG. 3, the first shielding pattern S1 and the second shielding pattern S2 are both connected to the first voltage connection pattern VDD3.

Specifically, referring to FIG. 6, the first voltage connection line VDD is located in the third conductive layer M3, and the first shielding pattern S1, the second shielding pattern S2 and the first voltage connection line VDD are disposed in a same layer. Further, the first shielding pattern S1, the second shielding pattern S2, and the first voltage connection pattern VDD3 have a one-piece structure.

In some implementations, as shown in FIG. 2, the display substrate further includes, in the wiring area PA, a second voltage connection line VSS disposed in the same layer as the first voltage connection line VDD, and one end of the second voltage connection line VSS is connected to the second bonding terminal BA20. As shown in FIG. 6, the second voltage connection line VSS is located in the third conductive layer M3. The second voltage connection line VSS is configured to transmit a second operating voltage signal, such as a high level voltage signal.

In some implementations, the second voltage connection line VSS includes a third portion connection line VSS1 and a fourth portion connection line VSS2, where the third portion connection line VSS1 passes through the first wire passing area QA1 and is connected to the second bonding terminal BA20, and is located on a side of a first portion connection line VDD1 away from the first bonding area BA1; the fourth portion connection line VSS2 passes through the second wire passing area QA2 and is connected to the second bonding terminal BA20, and is located on a side of the second portion connection line VDD2 away from the first bonding area BA1.

Specifically, the display substrate further includes the peripheral area surrounding the display area AA, one end of the third portion connection line VSS1 is connected to the second bonding terminal BA20, and the other end of the third portion connection line VSS1 extends into the peripheral area on the same side as the one end and is connected to a second operating voltage line in the display area AA; one end of the fourth portion connection line VSS2 is connected to the second bonding terminal BA20, and the other end of the fourth portion connection line VSS2 extends into the peripheral area on the same side as the one end and is connected to the second operating voltage line in the display area AA, so as to provide a second operating voltage signal to the pixel units in the display area AA.

In some implementations, as shown in FIG. 3, in the second wire passing area QA2, the second portion connection line VDD2 of the first voltage connection line VDD, the fourth portion connection line VSS2 of the second voltage connection line VSS, and the first connection lines L1 of the multiplexing signal lines MUX are sequentially arranged in a direction away from the first bonding area BA1, and are located in the same conductive layer, that is, all located in the third conductive layer M3. Further, the first connection lines L1 of the multiplexing signal lines are electrically connected to the second connection lines L2 through the third connection lines L3, and the third connection lines L3 inevitably overlap with the second portion connection line VDD2 and the fourth portion connection line VSS2 in the thickness direction of the display substrate.

In some implementations, as shown in FIG. 3, an orthographic projection of the second portion connection line VDD2 on the base substrate 10 and an orthographic projection of the fourth portion connection line VSS2 on the base substrate 10 both overlap with orthographic projections of the third connection lines L3 on the base substrate 10. Therefore, in order to prevent signal interference, the third connection lines L3 cannot be disposed in the same conductive layer as the second portion connection line VDD2 and the fourth portion connection line VSS2.

In some implementations, the third connection lines L3 are located in the first conductive layer M1 and/or the second conductive layer M2. That is, the third connection lines L3 are located on a side of the second portion connection line VDD2/the fourth portion connection line VSS2 close to the base substrate 10.

In some implementations, each multiplexing signal line MUX further includes: a fourth connection line L4, one end of the fourth connection line L4 is connected to the second connection line L2, and the other end of the fourth connection line L4 extends to the display area AA; and the first connection line L1 is connected to the second bonding terminal BA20. That is, each multiplexing signal line MUX receives a signal provided by the flexible printed circuit board, and outputs the signal to the conductive pattern in the display area AA via the first connection line L1, the third connection line L3, the second connection line L2, and the fourth connection line L4 sequentially. In some implementations, the fourth connection line L4 is located in the first conductive layer M1 and/or the second conductive layer M2.

It should be noted that as shown in FIG. 2, an area Q1 in FIG. 2 shows that the first connection line L1 and the second connection line L2 are connected to each other through a via hole, an area Q2 in FIG. 2 shows that the third connection line L3 and the second connection line L2 are also connected to each other through a via hole, and an area Q3 in FIG. 2 shows that the fourth connection line L4 and the second connection line L2 are connected to each other through a via hole. The third connection line L3 is located in the first conductive layer M1 and the second conductive layer M2, and the fourth connection line L4 and the third connection line L3 are arranged in the same manner, so that the connection between the fourth connection line L4 and the second connection line L2 and the connection between the third connection line L3 and the second connection line L2 are also the same. Based on this, the specific connection through the via holes in the Q1 area and the Q2 area in FIG. 2 will be described in detail in the following embodiment, and the connection in the Q3 area is not described again, and the detailed description refers to the following embodiment.

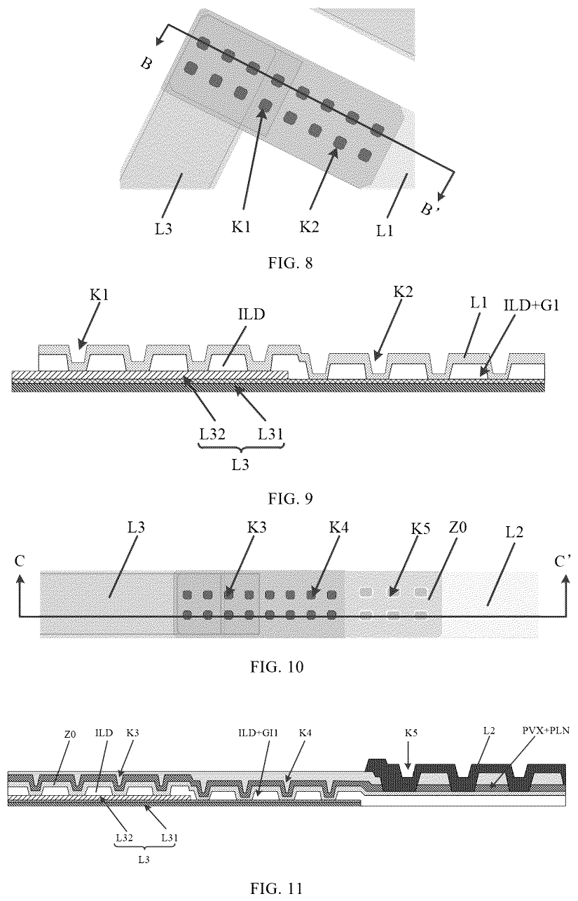

FIG. 8 is an enlarged schematic diagram of the area Q1 in FIG. 2. FIG. 9 is a cross-sectional view of the structure in FIG. 8 taken along a line BB′. FIG. 10 is an enlarged schematic diagram of an area Q2 in FIG. 2. FIG. 11 is a cross-sectional view of the structure in FIG. 10 taken along a line CC′.

As shown in FIGS. 8 and 9, the third connection line L3 includes a first portion L31 located in the first conductive layer M1 and a second portion L32 located in the second conductive layer M2, the first connection line L1 is connected to the second portion L32 through at least one first via hole K1 penetrating through the interlayer dielectric layer ILD, and the first connection line L1 is connected to the first portion L31 through at least one second via hole K2 penetrating through the interlayer dielectric layer ILD and the first insulating layer GI1.

It should be understood that the third connection line L3 is located in the first conductive layer M1 and the second conductive layer M2, which can reduce an impedance of the third connection line L3, improve the efficiency of the signal passing through the third connection line L3, and enhance the anti-interference capability of signals.

In addition, a plurality of first via holes K1 and a plurality of second via holes K2 are provided in the present disclosure, the conductive patterns in different conductive layers are connected to each other through the plurality of via holes, which can improve the connection stability between the third connection line L3 and the first connection line L1. For example, as shown in FIGS. 8 and 9, four first via holes K1 and four second via holes K2 are provided, and in other examples, other numbers of via holes may alternatively be provided, which is not limited in the present disclosure.

As shown in FIGS. 10 and 11, the third conductive layer M3 further includes an adapter pattern Z0; the first portion L31 of the third connection line L3 is connected to the adapter pattern Z0 through at least one third via hole K3 penetrating through the interlayer dielectric layer ILD and the first insulating layer GI1, and the second portion L32 of the third connection line L3 is connected to the adapter pattern Z0 through at least one fourth via hole K4 penetrating through the interlayer dielectric layer ILD; further, the adapter pattern Z0 is connected to the second connection line L2 through at least one fifth via hole K5 penetrating through the passivation layer PVX and the planarization layer PLN.

Like the Q1 area, a plurality of via holes are provided in the Q2 area. In an example, as shown in FIGS. 10 and 11, four third via holes K3 and four fourth via holes K are provided, and three fifth via holes K5 are provided.

In addition, as shown in FIG. 3, the display substrate further includes, in the peripheral area NA, a buffer layer BUF, an active semiconductor layer Poly, and the first insulating layer GI1 located between the base substrate 10 and the first conductive layer M1, and sequentially disposed in the direction away from the base substrate 10.

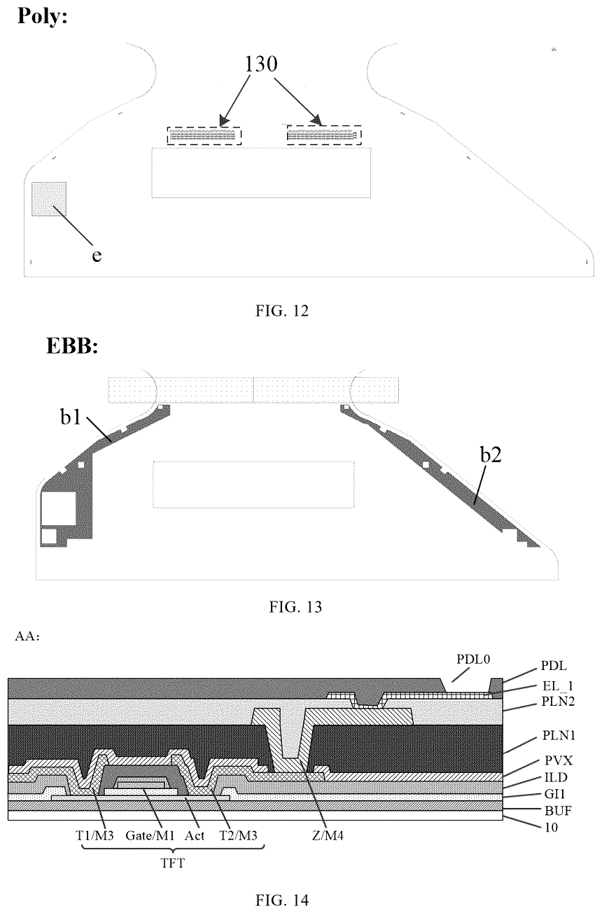

FIG. 12 is a schematic structural diagram of an active semiconductor layer in the peripheral area according to an embodiment of the present disclosure. As shown in FIG. 12, the ion injection is performed on a pattern formed on the active semiconductor layer Poly to perform a conductivization treatment on the pattern, so that the pattern is used as a touch conductive pattern 130 configured to be connected to the first bonding terminal BA10 to provide a touch signal. In addition, in FIG. 12, an alignment mark pattern e is further provided for facilitating the forming of layers in the peripheral area of the display substrate.

FIG. 13 is a schematic diagram of an etch bending B mask according to an embodiment of the present disclosure. An etch bending B mask (EBB mask) is used for performing an etching process on the interlayer dielectric layer ILD. Specifically, the interlayer dielectric layer ILD is formed on a side of the second conductive layer M2 away from the base substrate 10, where the interlayer dielectric layer ILD has a whole layer structure, and further, interlayer dielectric patterns in edge regions is etched away based on the EBB mask, as shown in FIG. 13, the edge regions may be a region b1 and a region b2. Interlayer dielectric patterns in the area b1 and the area b2 are etched away through the EBB process, so that a thickness of an edge of the display substrate in the peripheral area (that is, a thickness of each of the region b1 and the region b2) is advantageously reduced, and the bending processing of the peripheral area is facilitated.

FIG. 14 is a schematic structural diagram of a display area according to an embodiment of the present disclosure. In some implementations, as shown in FIG. 14, a plurality of data lines extending in the first direction Y and a plurality of gate lines arranged in the second direction X are disposed in the display area AA of the display substrate, and the plurality of data lines and the plurality of gate lines form a plurality of pixel units arranged in an array, where each pixel unit includes a light emitting device and a corresponding thin film transistor TFT. The thin film transistor TFT is configured to generate a driving signal and supply the driving signal to a corresponding light emitting device. Particularly, the thin film transistor TFT includes a gate electrode Gate, a source electrode T1, a drain electrode T2, and an active pattern Act. The drain electrode T2 of the thin film transistor TFT is connected to a first electrode of the light emitting device, and the source electrode T1 of the thin film transistor TFT is connected to the data line corresponding to the pixel unit.

The active pattern Act of the thin film transistor TFT includes a channel portion, and a source connection portion and a drain connection portion located on two opposite sides of the channel portion, where the source connection portion is connected to the source electrode T1, the drain connection portion is connected to the drain electrode T2, and the channel portion is opposite to the gate electrode Gate. When a voltage signal applied to the gate electrode reaches a certain value, a carrier path is formed in the channel portion, so that the source electrode T1 and the drain electrode T2 of the thin film transistor TFT are electrically connected to each other.

As shown in FIG. 14, the layers in the display area AA and the peripheral area NA of the display substrate are stacked in the same manner, and the display substrate includes, in the display area AA, the base substrate 10, and the buffer layer BUF, the active semiconductor layer Poly, the first insulating layer G1, the first conductive layer M1, the interlayer dielectric layer ILD, the third conductive layer M3, the passivation layer PVX, a first planarization layer PLN1, and the fourth conductive layer M4, which are located on a side of the base substrate 10 and are sequentially stacked in a direction away from the base substrate 10.

In addition, in the embodiment of the present disclosure, the thin film transistor TFT is of a top gate structure, and the gate electrode of the thin film transistor TFT is located on a side of the active pattern Act close to the source electrode and the drain electrode.

Specifically, the active semiconductor layer Poly includes the active pattern Act of the thin film transistor TFT, the first conductive layer M1 includes the gate electrode Gate and the gate lines (not shown), a second insulating layer GI2 is disposed on a side of the gate electrode Gate away from the base substrate, the third conductive layer M3 includes the source electrode T1 and the drain electrode T2 of the thin film transistor TFT, where the source electrode T1 is connected to the source connection portion of the active pattern Act through a via hole penetrating through the interlayer dielectric layer ILD and the first insulating layer GI1, the drain electrode T2 is connected to the drain connection portion of the active pattern Act through a via hole penetrating through the interlayer dielectric layer ILD and the first insulating layer GI1, and the drain electrode T2 of the thin film transistor TFT is connected to the first electrode EL_1 of the light emitting device through an adapter electrode Z disposed in the fourth conductive layer M4.

The first electrode EL_1 of the light emitting device may be an anode of the light emitting device, a pixel defining layer PDL is disposed on a side of the first electrode EL_1 of the light emitting device away from the base substrate 10, a plurality of accommodating grooves PDL0 are formed in the pixel defining layer PDL and arranged in an array, and each accommodating groove PDL0 is provided therein with a light emitting layer and a second electrode of the light emitting device.

It should be noted that the data lines (not shown in FIG. 14) are connected to the source electrodes T1 of the thin film transistors TFT, and the data lines and the source electrodes T1 of the thin film transistors TFT are disposed in the same layer, that is, the data lines are located in the third conductive layer M3 and are electrically connected to the data connection lines DL located in the peripheral area NA.

Based on the same inventive concept, an embodiment of the present disclosure further provides a display panel, which includes the display substrate provided in any one of the embodiments described above, and can achieve the same technical effects, which are not described herein again.

An embodiment of the present disclosure further provides a display apparatus, which includes the display panel.

The display apparatus may be: any product or component with a display function, such as electronic paper, a mobile phone, a tablet computer, a television, a display, a notebook computer, a digital photo frame, or a navigator or the like, which is not limited in the present disclosure described above.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display substrate, comprising a base substrate, wherein the base substrate comprises a display area and a peripheral area located on a side of the display area, and the peripheral area comprises a first bonding area and a wiring area surrounding the first bonding area;
in the wiring area, the display substrate comprises:
a plurality of data connection lines extending along a first direction;
a first shielding pattern electrically connected to a first voltage connection line; and
a plurality of multiplexing signal lines, wherein each multiplexing signal line comprises a first connection line, a second connection line, and a third connection line connecting the first connection line with the second connection line, and the first connection lines of the plurality of multiplexing signal lines are all located on a same side of the first bonding area in a second direction, and wherein
the plurality of data connection lines, the first shielding pattern, and the second connection lines are sequentially stacked in a direction away from the base substrate; and
an orthographic projection of each second connection line on the base substrate overlaps with an orthographic projection of a corresponding data connection line on the base substrate to form an overlapping part, and the overlapping part is located in an orthographic projection of the first shielding pattern on the base substrate.

2. The display substrate of claim 1, wherein, in the first bonding area, the display substrate comprises a plurality of first bonding terminals configured to be connected to a driving chip; and
one end of each data connection line is connected to a corresponding first bonding terminal, and the other end of the data connection line extends to the display area and is connected to a data line in the display area.

3. The display substrate of claim 1, wherein the peripheral area further comprises a second bonding area located on a side of the first bonding area away from the display area, and in the second bonding area, the display substrate comprises a plurality of second bonding terminals configured to be connected to a flexible printed circuit board;
each multiplexing signal line further comprises: a fourth connection line, one end of the fourth connection line is connected to the second connection line, and the other end of the fourth connection line extends to the display area; and
the first connection lines are connected to corresponding second bonding terminals.

4. The display substrate of claim 3, wherein the plurality of data connection lines comprise a plurality of first data connection lines and a plurality of second data connection lines, and orthographic projections of the plurality of first data connection lines on the base substrate and orthographic projections of the plurality of second data connection lines on the base substrate are respectively located on two opposite sides of an orthographic projection of the fourth connection line on the base substrate in the second direction; and
the orthographic projection of the first shielding pattern on the base substrate overlaps with the orthographic projections of the plurality of first data connection lines on the base substrate.

5. The display substrate of claim 4, wherein, in the wiring area, the display substrate further comprises: a second shielding pattern electrically connected to the first voltage connection line; and
an orthographic projection of the second shielding pattern on the base substrate overlaps with the orthographic projections of the plurality of second data connection lines on the base substrate.

6. The display substrate of claim 5, wherein the first voltage connection line comprises: a first portion connection line, a second portion connection line, and a first voltage connection pattern located between the first portion connection line and the second portion connection line;
wherein the first portion connection line and the second portion connection line are connected to corresponding second bonding terminals, and the first voltage connection pattern is connected to a conductive pattern located in the display area; and
the first shielding pattern and the second shielding pattern are connected to the first voltage connection pattern.

7. The display substrate of claim 6, wherein the wiring area comprises a first wire passing area and a second wire passing area, and the first wire passing area, the first bonding area and the second wire passing area are arranged in the second direction;
the first portion connection line passes through the first wire passing area and is connected to a corresponding second bonding terminal, and the second portion connection line passes through the second wire passing area and is connected to a corresponding second bonding terminal; and
the first voltage connection pattern is located on a side of the first bonding area close to the display area.

8. The display substrate of claim 5, wherein the first shielding pattern, the second shielding pattern and the first voltage connection line are disposed in the same layer.

9. The display substrate of claim 7, wherein, in the wiring area, the display substrate further comprises: a second voltage connection line in the same layer as the first voltage connection line, and one end of the second voltage connection line is connected to a corresponding second bonding terminal;
the second voltage connection line comprises a third portion connection line and a fourth portion connection line, and wherein
the third portion connection line passes through the first wire passing area and is connected to a corresponding second bonding terminal, and the third portion connection line is located on a side of a first portion connection line away from the first bonding area; and
the fourth portion connection line passes through the second wire passing area and is connected to a corresponding second bonding terminal, and the fourth portion connection line is located on a side of the second portion connection line away from the first bonding area.

10. The display substrate of claim 9, wherein an orthographic projection of the second portion connection line on the base substrate and an orthographic projection of the fourth portion connection line on the base substrate both overlap with an orthographic projection of the third connection line on the base substrate.

11. The display substrate of claim 1, wherein, in the first bonding area, the display substrate comprises a plurality of first bonding terminals configured to be connected to a driving chip;
the peripheral area further comprises a second bonding area located on a side of the first bonding area away from the display area, and in the second bonding area, the display substrate comprises a plurality of second bonding terminals configured to be connected to a flexible printed circuit board; and
in the wiring area, the display substrate further comprises a plurality of terminal connection lines configured to be connected to the plurality of first bonding terminals and the plurality of second bonding terminals.

12. The display substrate of claim 1, wherein, in the peripheral area, the display substrate comprises: a first conductive layer, a first insulating layer and a second conductive layer located on a side of the base substrate and sequentially arranged in the direction away from the base substrate; and
some of the plurality of data connection lines are located in the first conductive layer, and others are located in the second conductive layer.

13. The display substrate of claim 12, wherein the third connection lines are located in the first conductive layer and/or the second conductive layer.

14. The display substrate of claim 12, wherein each multiplexing signal line further comprises: a fourth connection line, one end of the fourth connection line is connected to the second connection line, and the other end of the fourth connection line extends to the display area, and the fourth connection line is located in the first conductive layer and/or the second conductive layer.

15. The display substrate of claim 12, wherein, in the peripheral area, the display substrate further comprises: a third conductive layer;
the third conductive layer is located on a side of the second conductive layer away from the base substrate, and the display substrate further comprises an interlayer dielectric layer arranged between the second conductive layer and the third conductive layer; and
the first connection lines are located in the third conductive layer.

16. The display substrate of claim 15, wherein the third connection line comprises a first portion located in the first conductive layer and a second portion located in the second conductive layer; and
the first connection line is connected to the second portion through at least one first via hole penetrating through the interlayer dielectric layer, and the first connection line is connected to the first portion through at least one second via hole penetrating through the interlayer dielectric layer and the insulating layer.

17. The display substrate of claim 15, wherein, in the peripheral area, the display substrate further comprises: a fourth conductive layer;
the fourth conductive layer is located on a side of the third conductive layer away from the base substrate, the display substrate further comprises a passivation layer and a planarization layer arranged between the third conductive layer and the fourth conductive layer, and the planarization layer is located on a side of the passivation layer away from the third conductive layer; and
the second connection line is located in the fourth conductive layer.

18. The display substrate of claim 17, wherein the third connection line comprises a first portion located in the first conductive layer and a second portion located in the second conductive layer,
the third conductive layer further comprises an adapter pattern;
the first portion is connected to the adapter pattern through at least one third via hole penetrating through the interlayer dielectric layer and the insulating layer, and the second portion is connected to the adapter pattern through at least one fourth via hole penetrating through the interlayer dielectric layer; and
the adapter pattern is connected to the second connection line through at least one fifth via hole penetrating through the passivation layer and the planarization layer.

19. A display panel, comprising the display substrate of claim 1.

20. A display apparatus, comprising the display panel of claim 19.
